(19) United States
(12) Patent Application Publication
(10) Pub. No.: US 2006/0182105 A1
(43) Pub. Date: Aug. 17, 2006

(54) Apparatus and method for transmitting multi protocol label switching (MPLS) multicast packets over Ethernet

(76) Inventors: Jin-Hyoung Kim, Suwon-si (KR); Byung-Chang Kang, Yongin-si (KR); Yong-Seok Park, Yongin-si (KR)

Correspondence Address: ROBERT E. BUSHNELL, 1522 K STREET NW, SUITE 300, WASHINGTON, DC, 20005-1202, US

(21) Appl. No.: 11/328,464

(22) Filed: Jan. 10, 2006

(30) Foreign Application Priority Data
Jan. 11, 2005 (KR) 10-2005-0002651

(51) Int. Cl. H04L 12/56; H04L 12/28

(52) U.S. Cl. 370/389; 370/400

(57) ABSTRACT

An apparatus and method for transmitting multi-protocol label switching (MPLS) multicast packets over Ethernet are provided. The apparatus and method determine whether a received packet is an MPLS multicast packet; determine whether an address of the received packet exists in a database storing address information for MPLS multicast packet transmission; determine which node the MPLS multicast packet whose address exists in the database is transmitted to and allocating an MPLS label according to the address of the determined node; and map the allocated MPLS label to an Ethernet destination MAC address of the packet in order to realize simple switching by mapping an MPLS label, rather than a conventional IP address, to an Ethernet destination medium access control (MAC) address, thereby utilizing advantages of an MPLS network.

### CLAIM OF PRIORITY

This application makes reference to, incorporates the same herein, and claims all benefits accruing under 35 U.S.C. §119 from an application for APPARATUS AND METHOD FOR TRANSMITTING MULTI PROTOCOL LABEL SWITCHING (MPLS) MULTICAST PACKETS ON ETHERNET, earlier filed in the Korean Intellectual Property Office on Jan. 11, 2005 and there duly assigned Serial No. 10-2005-0002651.

### BACKGROUND OF THE INVENTION

1. Field of the Invention

The present invention relates to an apparatus and method for transmitting multi-protocol label switching (MPLS) multicast packets over Ethernet, and more particularly, to an apparatus and method for transmitting MPLS multicast packets over Ethernet utilizing advantages of an MPLS network of simplified packet delivery.

2. Description of the Related Art

Multi-protocol label switching (MPLS) has been introduced as a core technique for packet switching in a core network because it has a simplified packet delivery function and a traffic engineering-based overhead distribution function. However, MPLS functions have been developed focusing on unicast packet transmission rather than multicast support.

An apparatus and method for transmitting MPLS multicast packets over Ethernet have not yet been developed. At present, a method for transmitting IP multicast packets over Ethernet is equally applied to MPLS multicast packet transmission. That is, current MPLS multicast packet transmission via Ethernet is achieved by mapping an IP multicast group address of an MPLS multicast packet to an Ethernet medium access control (MAC) address.

FIGS. 1 and 2 show such conventional art. FIG. 1 illustrates a method for mapping an IP multicast group address contained in an MPLS multicast packet to an Ethernet MAC address, and FIG. 2 is a flowchart illustrating a conventional multicast address joining process. An Ethernet multicast address consists of the multicast bit, the 23-bit vendor component, and the 24-bit group identifier assigned by the vendor. FIG. 1 corresponds to an Internet standard bit-order, and is the format that most programmers have to deal with.

Referring to FIG. 1, the lower 23 bits of an IP multicast group address, owned by the Internet Assigned Numbers Authority (IANA), an organisation that oversees IP address, top level domain and Internet protocol code point allocations, are mapped to last 23 bits of an Ethernet MAC address and a predefined prefix fills remaining bits of Ethernet MAC address.

FIG. 2 shows a process in which a node participating in a multicast network performs multicast joining beginning at an application layer 200 to receive multicast packets. Referring to FIG. 2, when an Ethernet device driver 220 receives a multicast packet, it retrieves a joined multicast address database 222, and when the address of the received packet is an address joined by Ethernet device driver 220, it transmits the packet to an OS network stack 210.

However, in the MPLS multicast packet transmission in which an IP multicast group address is mapped to an Ethernet MAC address, it is necessary to check an IP packet encapsulated with the MPLS multicast packet to identify an IP multicast group address each time the packet is transmitted. Consequently, advantages of the MPLS are not utilized and packet delivery is inefficient. Accordingly, there is a need for an apparatus and method for transmitting multi-protocol label switching (MPLS) multicast packets over Ethernet that are capable of utilizing the advantages of the MPLS to solve the aforementioned problems.

References of interest to the invention are: Network Working Group Request for Comments (RFC) 2746 “RSVP Operation Over IP Tunnels”; Network Working Group Request for Comments (RFC) 3031 “Multiprotocol Label Switching Architecture”; Network Working Group Request for Comments (RFC) 3032 “MPLS Label Stack Encoding”; Network Working Group Request for Comments (RFC) 3036 “LDP Specification”; Network Working Group Request for Comments (RFC) 3812 “Multiprotocol Label Switching (MPLS) Traffic Engineering (TE) Management Information Base (MIB)”; and Network Working Group Request for Comments (RFC) 3815 “Definitions of Managed Objects for the Multiprotocol Label Switching (MPLS), Label Distribution Protocol (LDP)”.

### SUMMARY OF THE INVENTION

It is an object of the present invention to provide an apparatus and method capable of transmitting MPLS multicast packets over Ethernet using a multi-protocol label switching (MPLS) label.

According to an aspect of the present invention, there is provided an apparatus for transmitting a multi-protocol label switching (MPLS) multicast packet at each node in an Ethernet network comprising at least one node, the apparatus including: a database for storing address information for MPLS multicast packet transmission; a determiner for determining whether a packet received from another node is the MPLS multicast packet, and when the received packet is the MPLS multicast packet, determining whether an address of the received packet exists in the database; a packet processor for determining which node the MPLS multicast packet whose address exists in the database is transmitted to and allocating an MPLS label according to an address of the determined node; and a mapper for mapping the allocated MPLS label to an Ethernet destination medium access control (MAC) address of the packet.

According to another aspect of the present invention, there is provided a method for transmitting a multi-protocol label switching (MPLS) multicast packet at each node in an Ethernet network comprising at least one node, the method including: a first step of receiving a packet; a second step of determining whether the received packet is the MPLS multicast packet; a third step of, when the received packet is the MPLS multicast packet, determining whether an address of the received packet exists in a database, the database storing address information for MPLS multicast packet transmission; a fourth step of determining which node the MPLS multicast packet whose address exists in the database is transmitted to and allocating an MPLS label according to the address of the determined node; and a fifth step of mapping the allocated MPLS address to an Ethernet destination MAC address of the packet.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings, in which like reference symbols indicate the same or similar components, wherein:

FIG. 1 illustrates a method for mapping an IP multicast group address contained in an MPLS multicast packet to an Ethernet MAC address;

FIG. 2 is a flowchart illustrating a conventional multicast address joining process;

FIG. 3 illustrates a signaling process for multicast packet transmission in an MPLS network;

FIG. 4 illustrates a process for multicast packet transmission in an MPLS network;

FIG. 5 illustrates a portion of a format for a hello message suggested for signaling according to the present invention;

FIG. 6 illustrates the format of a packet that may be used in the present invention;

FIG. 7 illustrates mapping an MPLS multicast label to an Ethernet MAC address;

FIG. 8 illustrates multicast address joining according to the present invention;

FIG. 9 illustrates a packet transmission apparatus for transmitting a MPLS multicast packet over Ethernet using a determined and allocated MPLS label according to the present invention; and

FIG. 10 is a flowchart illustrating an MPLS multicast packet transmission and reception process over Ethernet according to the present invention.

### DETAILED DESCRIPTION OF THE INVENTION

The present invention will now be described more fully with reference to the accompanying drawings, in which preferred embodiments of the invention are shown. This invention may, however, be embodied in different forms and should not be construed as being limited to the embodiments set forth herein. Rather, these embodiments are provided so that this disclosure will be thorough and complete, and will fully convey the concept of the invention to those skilled in the art.

In the present invention described below, a method is used for mapping a multi-protocol label switching (MPLS) label to an Ethernet MAC address in order to transmit MPLS multicast packets over Ethernet using only the MPLS label.

To this end, the present invention suggests a method for mapping an MPLS multicast label to an Ethernet MAC address, an algorithm for transmitting an MPLS multicast packet with Ethernet MAC address to which the MPLS multicast label is mapped over Ethernet, and an MPLS signal protocol extension for discovering a node in a network supporting the present invention.

Meanwhile, Ethernet MAC addresses may be classified into an Ethernet source MAC address and an Ethernet Destination MAC address. Mapping is performed on Ethernet destination MAC address. Accordingly, the term “Ethernet MAC” refers to Ethernet destination MAC herein.

A network according to the present invention and multicast packet transmission in the network will be described first with reference to the accompanying drawings. The present invention includes at least one node, e.g., a router, a switch, or the like, and may be applied to an Ethernet-based MPLS network.

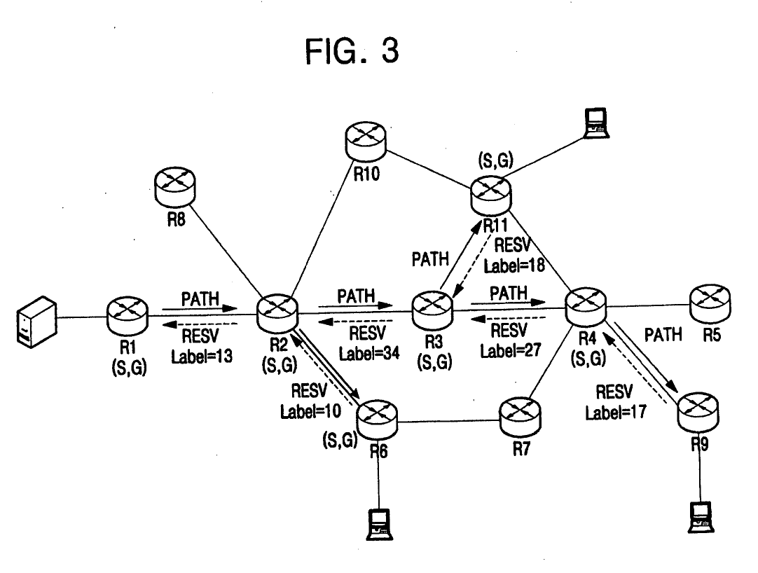

FIG. 3 illustrates a signaling process for multicast packet transmission in an MPLS network. Packets are transmitted on the network using the labels.

A signaling process shown in FIG. 3 is used to identify a path label in a relevant network. As shown in FIG. 3, in a branch node, e.g., R2 and R3, in which one or more downstream routers (Rn, where R is a node, and n is an integer 1, 2, 3, . . . ) have joined a multicast group, a PATH message should be replicated and forwarded to a relevant router. An RESV message should be merged at a branch node and forwarded to an upstream router as a response to the PATH. In multicast S, G, the symbol “S” denotes a source and “G” denotes a group.

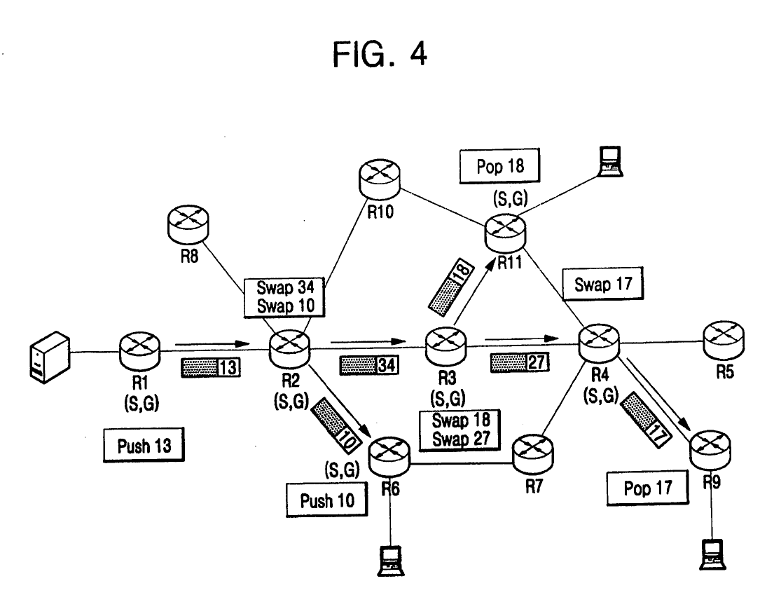

FIG. 4 illustrates a process for multicast packet transmission in an MPLS network.

After the label is identified in the signaling process shown in FIG. 3, each node transmits a multicast packet as in FIG. 4. That is, when each node receives an MPLS multicast packet, it performs label operation on a next hop (node) by referring to a multicast label transfer table, and then transmits the packet. When receiving one MPLS multicast packet, a branch node should replicate and transmit received MPLS multicast packets to all nodes for which an MPLS multicast label switching path (LSP) has been established. For example, referring to FIG. 4, when R2 receives a packet having label 13 from R1, it changes the label 13 of the received packet into 34 and transmits the changed packet to R3, and also changes the label 13 of a received packet into 10 and transmits the changed packet to R6. Packet transmission at other nodes shown in FIG. 4 is the same and further description thereof will be omitted.

Meanwhile, each node included in such a network may be a node that is able to support the present invention or a node that is unable to support the present invention. Typically, to transmit the MPLS multicast packet using the present invention in which an MPLS multicast label is mapped to an Ethernet MAC address, all MPLS nodes on a relevant Ethernet link should support this function. Accordingly, there is a need for a method capable of identifying whether each node supports the present invention. In this case, an MPLS signal protocol is extended to enable a node on the network supporting the present invention to be discovered. To extend the signal protocol, a hello message that additionally contains an MPLS multicast parameter TLV (Type, Length and Value) is used. TLV is a methodology for coding parameters within a frame. Type indicates the parameter type, length indicates the length of its value, and value indicates the value of parameter.

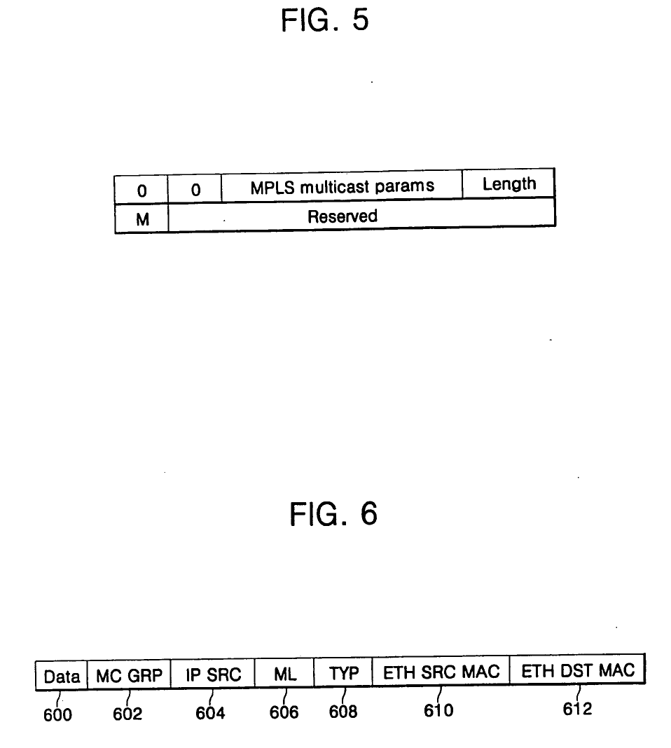

FIG. 5 illustrates a portion of a format for a hello message suggested for signaling according to the present invention.

In the format shown in FIG. 5, ‘M’ is a flag indicating whether an Ethernet interface having an MPLS function supports mapping an MPLS label to an Ethernet MAC address. For example, the value ‘1’ of M indicates that Ethernet interface supports mapping an MPLS label to an Ethernet MAC address according to the present invention. A value ‘0’ indicates that Ethernet interface does not support such mapping according to the present invention. It will be apparent that the values of ‘M’ in the present invention are not limited to such numerical representation but may be represented in a different manner. Other elements of the hello message format shown in FIG. 5 are known in typical MPLS signal protocol and therefore will not be described.

The hello message shown in FIG. 5 may be used in the signaling process of FIG. 3. The use of the hello message enables a node supporting the present invention to be identified.

A method of mapping an MPLS multicast label to an Ethernet MAC address according to the present invention will be now described.

FIG. 6 illustrates the format of a packet that may be used in the present invention.

As shown in FIG. 6, a packet used in the present invention may contain data 600, an IP multicast group address (MC GRP) 602, an IP multicast source address (IP SRC) 604, a multicast label (ML) 606, a packet type (TYP) 608, an Ethernet multicast source MAC address (ETH SRC MAC) 610, and an Ethernet multicast destination MAC address (ETH DST MAC) 612 fields. The data field 600 is data to be transmitted by a relevant packet, the IP multicast group address field 602 and the IP multicast source address field 604 are IP headers, and the multicast label 606 is used to transmit packets in the multicast network. The packet type field 608 is used to identify the type of the packet. For example, if the packet type field 608 has a value of 0×8848 the packet may be an MPLS multicast packet. The Ethernet source MAC address field 610 and the Ethernet destination MAC address field 612 may correspond to Ethernet headers used for packet transmission in Ethernet.

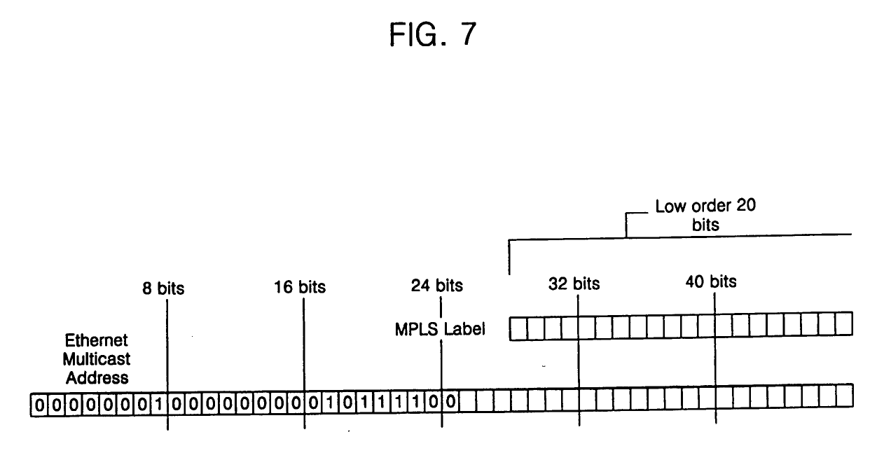

In the present invention, the multicast label field 606 is mapped to the Ethernet destination MAC address field 612 to realize MPLS multicast packet transmission via Ethernet. This is shown in FIG. 7.

FIG. 7 illustrates mapping an MPLS multicast label to an Ethernet MAC address.

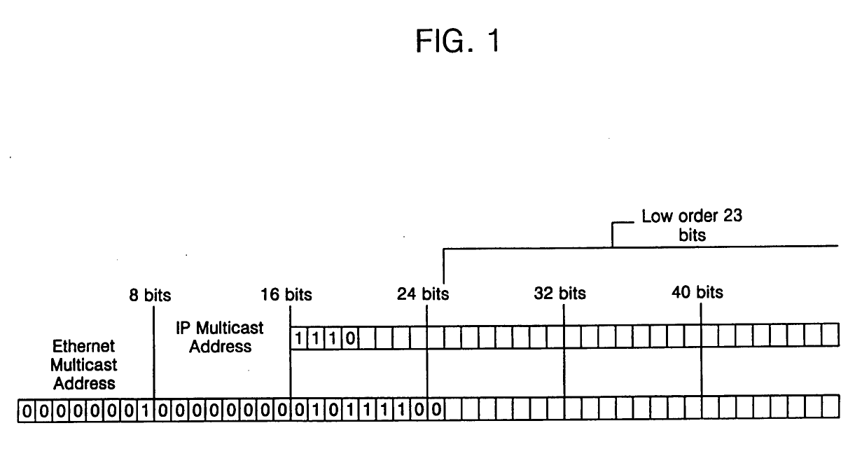

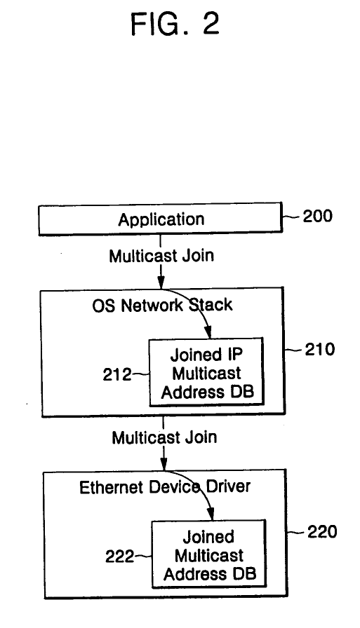

In the present invention, the MPLS multicast label is mapped to lower 20 bits of the Ethernet MAC address, as shown in FIG. 7. Remaining bits of the Ethernet MAC address may be obtained by the IP multicast group address mapping as shown in FIG. 1 or may be filled with a specially defined prefix.

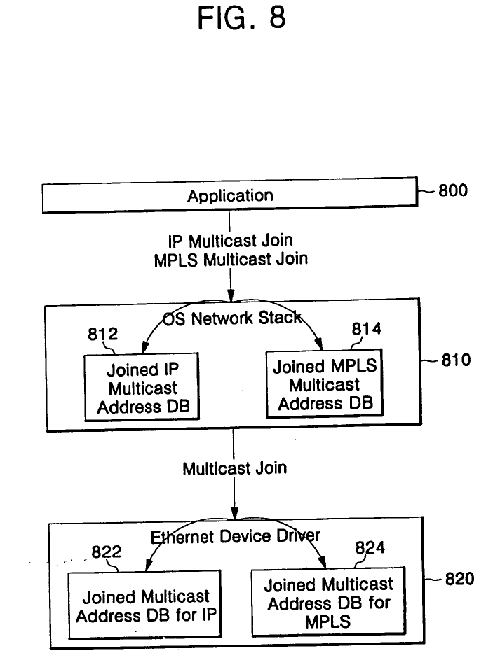

FIG. 8 illustrates multicast address joining according to the present invention.

FIG. 8 shows a process in which a node participating in a multicast network performs multicast joining beginning at an application layer 800 to receive a multicast packet. The joining process is used to set information related to packet transmission at a relevant node by referring to the information collected through the signaling process shown in FIG. 3. In other words, the joining process sets information about an address of a node to which the packet will be transmitted, based on an address of a received packet, e.g., based on information needed for packet transmission, such as an IP address, an MPLS label, and the like.

In the present invention, the IP multicast joining and the MPLS multicast joining are performed separately. That is, an OS network stack 810 and an Ethernet device driver 820 include respective databases 812 and 822 that store IP multicast addresses. The OS network stack 810 and the Ethernet device driver 820 further include respective databases 814 and 824 that store MPLS multicast addresses.

In FIG. 8, when the Ethernet device driver 820 receives a multicast packet, it checks the type of the received packet. Specifically, the Ethernet device driver 820 checks whether the received multicast packet is an IP multicast packet or an MPLS multicast packet. After the Ethernet device driver 820 checks the type of the received packet, it retrieves the corresponding joined multicast address database 822 or 824 to check whether an address of the received packet is an address that the Ethernet device driver 820 has joined. That is, the Ethernet device driver 820 retrieves the database 822 for IP when the received packet is an IP multicast packet, and retrieves the database 824 for MPLS when the received multicast packet is an MPLS multicast packet. When the packet address exists in the database, the Ethernet device driver 820 transmits the packet to the OS network stack 810.

The OS network stack 810 determines operation and an outgoing interface for the MPLS multicast packet which is received from Ethernet device driver 820.

With the present invention described above, it is possible to transmit the MPLS multicast packet over Ethernet using only the MPLS label.

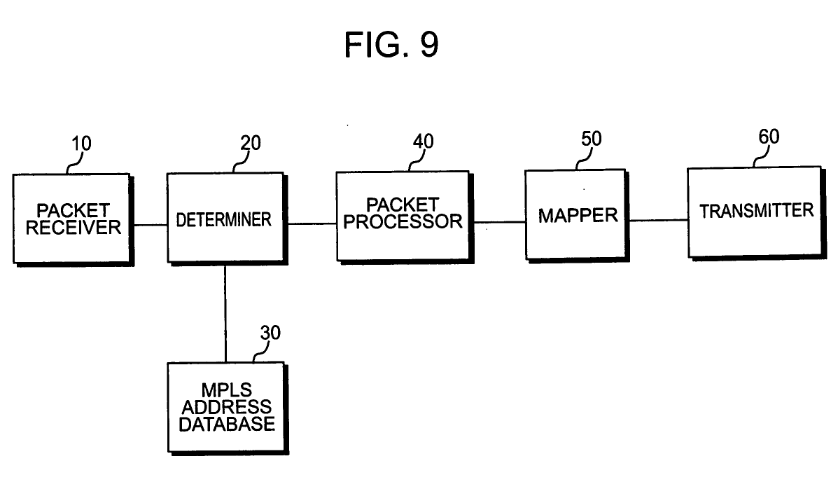

That is, as shown in FIG. 9, the packet transmission apparatus according to the present invention may include a database 30 that stores an MPLS multicast packet address, a packet receiver 10; a determiner 20 for determining the type of the received packet, i.e., whether the received packet is an IP multicast packet or an MPLS multicast packet, and determining whether an address of the received packet is stored in the database 30; a packet processor 40 for determining which node, i.e., interface, the packet whose address is stored in the database 30, i.e., a joined packet, is transmitted to, and determining an MPLS label to be allocated to the packet based on the determined interface; a mapper 50 for mapping the MPLS label allocated to the packet to the Ethernet destination MAC address 612 of the packet; and a packet transmitter 60 for transmitting the mapped packet.

MPLS multicast packet transmission over Ethernet according to the present invention will now be described.

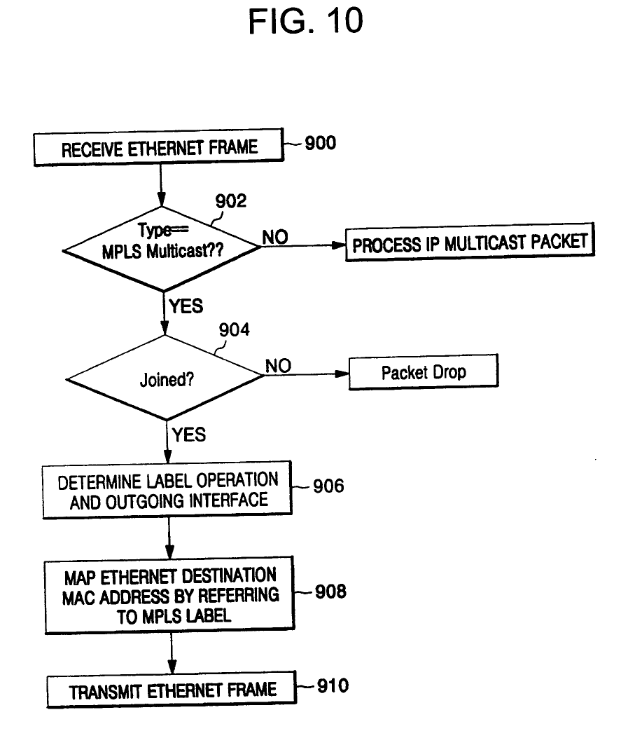

FIG. 10 is a flowchart illustrating an MPLS multicast packet transmission and reception process over Ethernet according to the present invention.

The packet transmission apparatus according to the present invention receives an Ethernet frame/packet (900) and determines whether the received packet is an MPLS multicast packet (902). This determination may be made by checking a value of the packet type field 608 of the received packet. When the packet transmission apparatus of the present invention determines that the received packet is not the MPLS multicast packet but is the IP multicast packet, the packet transmission apparatus processes the received packet according to an IP multicast packet processing method. In this case, reference is made to the description of the conventional art.

The packet transmission apparatus of the present invention checks whether an Ethernet MAC address of the packet determined to be the MPLS multicast packet is stored in the MPLS multicast packet database (904). When the Ethernet MAC address of the packet is stored in the MPLS packet database, the packet transmission apparatus of the present invention goes into step 906, and when the address of the packet is not stored in the database, the packet transmission apparatus of the present invention determines the packet to be an erroneously transmitted packet and drops the packet. These processes are performed at the Ethernet device driver 820.

The packet transmission apparatus of the present invention determines a label operation for the MPLS multicast packet whose address exists in the database and an outgoing interface for the packet, and allocates an MPLS label to the packet according to the determined interface (906). Further, the packet transmission apparatus of the present invention maps the MPLS label allocated to the packet to an Ethernet MAC address of the packet (908). The packet transmission apparatus of the present invention transmits the fram/packet with the Ethernet MAC address to which the MPLS label is mapped (910).

The present invention described above with reference to FIGS. 3 to 10 may be summarized as follows:

The MPLS signal protocol discovers the MPLS node on the Ethernet network shown in FIG. 3 through exchange of the hello message shown in FIG. 5. In particular, the hello message of FIG. 5 may be used to discover an MPLS node to which the present invention is applied. In this case, if there is an MPLS multicast parameter TLV in the hello message and the ‘M’ flag of the hello message is set as ‘1’, it is determined that a relevant node supports the method for mapping the MPLS multicast label to the Ethernet MAC address. If there is no MPLS multicast parameter TLV in the hello message or the ‘M’ flag is set as ‘0’, a packet transmission method for mapping the IP multicast group address is used since the node does not support the method for mapping the MPLS multicast label to the Ethernet MAC address.

If all MPLS nodes support the present invention, the MPLS signal protocol performs the MPLS multicast joining to the OS network stack 810 and the Ethernet device driver 820 using a relevant label when the MPLS signal protocol receives or sets multicast label binding information.

When each node receives an MPLS multicast packet, it transmits the packet to the OS network stack 810 or an MPLS multicast packet delivery engine by referring to the joined multicast database 824 for MPLS in the Ethernet device driver 820.

Meanwhile, when transmitting the MPLS multicast packet, each node performs the label operation and determines the outgoing interface by referring to the MPLS multicast packet delivery table. The packet with the thus determined MPLS label is transmitted with the Ethernet MAC address containing the predefined prefix and the lower 20 bits to which the MPLS label is mapped.

That is, the present invention enables a packet to be transmitted using only an MPLS multicast label without referring to an IP header in MPLS multicast packet transmission over Ethernet.

With the present invention, when an MPLS multicast packet is transmitted over Ethernet, it is not necessary to refer to an IP header encapsulated with an MPLS label, thereby eliminating inefficient packet delivery and enabling high-speed packet delivery.

While the present invention has been described with reference to exemplary embodiments thereof, it will be understood by those skilled in the art that various changes in form and detail may be made therein without departing from the scope of the present invention as defined by the following claims.

What is claimed is:

1. An apparatus for transmitting a multi-protocol label switching (MPLS) multicast packet at each node in an Ethernet network comprising at least one node, the apparatus comprising:
a database for storing address information for MPLS multicast packet transmission;
a determiner for determining whether a packet received from another node is the MPLS multicast packet, and when the received packet is the MPLS multicast packet, determining whether an address of the received packet exists in the database;
a packet processor for determining which node the MPLS multicast packet in which the address exists in the database is transmitted to and allocating an MPLS label according to an address of the determined node; and
a mapper for mapping the allocated MPLS label to an Ethernet destination medium access control (MAC) address of the packet.

2. The apparatus according to claim 1, further comprising:
a transmitter for receiving the packet from the mapper and transmitting the received packet, the received packet having the Ethernet destination MAC address to which the MPLS label has been mapped.

3. The apparatus according to claim 1, wherein the determiner determines whether the received packet is the MPLS multicast packet by referring to a packet type field contained in the received packet.

4. The apparatus according to claim 1, wherein the mapper maps the MPLS label allocated to the packet to lower 20 bits of the Ethernet destination MAC address of the packet.

5. The apparatus according to claim 4, wherein the mapper maps a predefined prefix to remaining bits other than the bits to which the MPLS label is mapped.

6. The apparatus according to claim 1, wherein the node in the Ethernet network has a function of mapping the MPLS label to the Ethernet destination MAC address.

7. The apparatus according to claim 6, wherein a determination as to whether the Ethernet node has the function of mapping the MPLS label to the Ethernet destination MAC address is made using a hello message with a check flag.

8. An apparatus for transmitting a multi-protocol label switching (MPLS) multicast packet at each node in an Ethernet network comprising at least one node, the apparatus comprising:
a first database for storing address information for MPLS multicast packet transmission;
a second database for storing address information for IP multicast packet transmission;
a determiner for determining the type of a packet received from another node, determining whether an address of the received packet exists in the first database when the received packet is the MPLS multicast packet, and determining whether an address of the received packet exists in the second database when the received packet is an IP multicast packet;
a packet processor for determining which node the packet whose address exists in the first database or the second database is transmitted to and allocating the address of the determined node to the packet; and
a mapper for mapping the allocated address to an Ethernet destination MAC address of the packet.

9. The apparatus according to claim 8, wherein when the packet is the MPLS multicast packet, an address allocated to the packet by the packet processor is an MPLS label.

10. A process for transmitting a multi-protocol label switching (MPLS) multicast packet at each node in an Ethernet network comprising at least one node performing a method comprising steps of:
receiving a packet;
determining whether the received packet is the MPLS multicast packet;
determining whether an address of the received packet exists in a database when the received packet is the MPLS multicast packet, the database storing address information for MPLS multicast packet transmission;
determining which node the MPLS multicast packet whose address exists in the database is transmitted to and allocating an MPLS label according to the address of the determined node; and
mapping the allocated MPLS label to an Ethernet destination MAC address of the packet.

11. The method according to claim 10, wherein the step of determining whether the received packet is the MPLS multicast packet comprises determined whether the received packet is the MPLS multicast packet by referring to a packet type field contained in the received packet.

12. The method according to claim 10, wherein the step of mapping comprises mapping the MPLS label to lower 20 bits of the Ethernet destination MAC address of the packet.

13. The method according to claim 12, wherein the step of mapping comprises mapping a predefined prefix to remaining bits other than the bits to which the MPLS label is mapped.

14. The method according to claim 10, further comprising a step of determinating, by exchange of a hello message with a check flag, whether the Ethernet node is able to map the MPLS label to the Ethernet destination MAC address.

15. The method according to claim 10, further comprising steps of:
exchanging a hello message between nodes of the Ethernet network; and
determining whether there is an MPLS multicast parameter TLV (type, length and value) in the hello message;
determining whether an ‘M’ flag of the hello message is set as logical ‘1’ or logical ‘0’; and
determining that a relevant node supports the method for mapping the MPLS label to the Ethernet destination MAC address when it is determined that the hello message includes the MPLS multicast parameter TLV (type, length and value) and that the ‘M’ flag of the hello message is set as logical '1’.

16. The method according to claim 15, further comprising determining that a relevant node does not support the method for mapping the MPLS label to the Ethernet destination MAC address when it is determined that the hello message does not include the MPLS multicast parameter TLV (type, length and value) or that the ‘M’ flag of the hello message is set as logical ‘0’.
